(19) United States
(12) Patent Application Publication
(10) Pub. No.: US 2006/0213842 A1
(43) Pub. Date: Sep. 28, 2006

(54) Supporting shelf for front opening unified pod

(76) Inventors: Yonatan Shani, Kibbutz Ein-Harod Ihud (IL); Zur Friedman, Kibbutz Ein-Harod Ihud (IL)

Correspondence Address: TIAJOLOFF & KELLY, CHRYSLER BUILDING, 37TH FL, 405 LEXINGTON AVE, NEW YORK, NY, 10174, US

(21) Appl. No.: 11/295,169

(22) Filed: Dec. 5, 2005

Related U.S. Application Data
(63) Continuation-in-part of application No. PCT/IL04/00476, filed on Jun. 3, 2004.
(60) Provisional application No. 60/475,776, filed on Jun. 5, 2003.

(51) Int. Cl. A47G 25/06; H01L 21/306

(52) U.S. Cl. 211/1; 156/345.1

(57) ABSTRACT

A support extendible shelf for a container such as a Front Opening Unified Pod (“FOUP”) wafer container. The shelf may host a FOUP designed for large diameter wafers such as 200 mm or greater wafer. The support shelf may facilitate quick load and unload of a container such as a FOUP. The support shelf may also facilitate control over atmospheric conditions inside the container FOUP BY interacting with a control system. The extendible shelf may have a fixed body and a retractable body on which a container may be placed. The extendible shelf may be in a fully out (extended) position, for allowing to lay thereon or remove therefrom a container, whichever the case may be, or in a fully in (stowed) position. The extendible shelf may be in any position between the fully out position and the fully in position, in which position the atmospheric conditions inside the container may be controlled.

### BACKGROUND

In connection with microelectronics, a wafer is a thin slice of semiconducting material, such as a silicon crystal, used in the electronic “chip” or microelectronics industry, upon which microcircuits are constructed by doping (for example, by diffusion or ion implantation), etching and deposition of various materials. Wafers are made in various sizes, as, for example, ranging from 1 inch (25.4 mm) to 11.8 inches (300 mm), and usually very thin, such as a common thicknesses of the order of about 0.5 mm to 1.0 mm. Generally, wafers are cut from a boule or ingot of semiconductor substrtae material, such as silicon, Gallium Arsenide or Germanium, using a diamond saw, for example, and then often lapped and/or polished on one or both faces. Wafers are of key importance in the fabrication of semiconductor microelectronic devices such as integrated circuits.

Wafers are susceptible to contamination and oxidation, which may degrade the electrical performance of the microcircuit constructed thereon. Excess levels of contamination or oxidation may even render the microcircuit inoperative. Therefore, wafers should be stored prior to use, for example in a pod, under surrounding conditions, which may reduce the contamination, including by oxygen, to a bearable level. The move of the industry to larger-scale wafers, such as 300-mm wafers, with even smaller lithographic and other process allowances for micro circuit element minimum feature size, create new demands and needs in this field.

Currently, wafers are stored in containers known as Front Opening Unified Pod (“FOUP”). The FOUP is a 300 mm wafer handling and contamination control device, used in the semiconductor manufacturing industry. Pods are used to transport wafers between processes, and care must be taken when using the pods to avoid wafer contamination. For example, the presence of humidity in the enclosed environment of the pods can cause a variety of phenomena, such as native oxide growth, corrosion, and film cracking. FOUP is more described at “Fluent NEWS—Spring 2004—Preventing Wafer Contamination”, by Roland Bernard and Hisanori Kambara, Alcatel Vacuum Technology, Annecy, France; and Arnaud Favre, INOPRO, Grenoble, France.

### SUMMARY

The following embodiments and aspects thereof are described and illustrated in conjunction with systems, tools and methods, which are meant to be exemplary and illustrative, not limiting in scope. In various embodiments, one or more of the above-described problems have been reduced or eliminated, while other embodiments are directed to other advantages or improvements.

By “retractably extendible” is meant hereinafter an element, or body, that may extend, or retract, from an initial position and, when in extended or retracted position, it may retract or extend, respectively, back to its initial position. The term “extension” refers hereinafter to bringing a retractably extendible body to a fully-out position or to a fully-in position, or to any position between the fully-out and fully-in positions. The term “docking” refers hereinafter to placing a container on a retractably extendible shelf in a way that no undesired relative lateral movement can occur between the container and the retractably extendible body of the shelf. The term “agent” refers herein to a substance that can be gaseous (for example, Nitrogen or dry air) though this is not necessarily so. The term “connect” refers hereinafter to a shelf valve and to a container valve being mutually engaged such that no material can leak from/to the container through the valves that only enable flow of the agent in normal operation, as described hereinafter.

As part of the present disclosure, an apparatus is provided for enabling control over storage conditions of semiconductor wafers. According to some embodiments, the apparatus may include a retractably extendible shelf adaptable for supporting a container such as a FOUP. The apparatus may further include at least one docking member for docking thereon a container, and at least one shelf valve adaptable to be engageable with a container valve to form an open passage through which the interior atmosphere of the container may be controlled by providing, through the open passage, an atmosphere-controlling agent.

According to some embodiments, the open passage may be formed formed as a result of the pressure exerted by one (the shelf or the container) valve on the other (the container or the shelf) valve when the container is docked on the extendible shelf.

According to some embodiments, the state of the retractably extendible shelf may be controllably and variously extended between a fully-out (“extended”) position and a fully in (“stowed”) position. The extended position may be used for placing, or removing, a container on/from the retractably extendible shelf, whereas the stowed position may be used for controlling the atmosphere inside the container. By ‘controlling the atmosphere inside the container’ is meant controlling at least the oxygen and relative humidity levels inside the container.

According to some embodiments, the extendible shelf may include a first, fixed, body and a second, retractably extendible body. The retractable body may be adaptable to be slidably moved relative to the fixed body in both ways between the stowed position and the extended position.

According to one aspect, the docking member may be a pin, or a male-like member, that may protrude from the retractably extendible body, though this is not necessarily so, and may be adapted to be engaged with a respective cavity, or female-like member, in the container. According to another aspect, the docking member may be a cavity, or a female-like member, in the retractably extendible body, which is adapted to be engaged with a pin, or male-like member, protruding from the container.

According to some embodiments, the apparatus may further include a location detector for detecting when the extendible shelf is in pre-defined location, such as in a “stowed” position and, according to one aspect, the passage of the atmosphere-controlling agent into the container may be automatically enabled only if the location detector detects that the shelf is in a pre-defined position. In one aspect of the present disclosure, the pre-defined position may be the stowed position.

According to some embodiments, the apparatus may further include a control interface for remotely controlling the movement of the retractably extendible body and the provision of the atmosphere-controlling agent to the shelf valve, and for remotely monitoring the atmospheric conditions inside the container.

According to some embodiments, the apparatus may further include a user interface for bypassing the control interface, for locally controlling the movement of the retractably extendible body and the provision of the atmosphere-controlling agent to the valve, and for displaying data relating to atmospheric conditions inside the container.

As part of the present disclosure, a system is provided for managing a plurality of containers. The system may include a plurality of retractably extendible shelves having a docking member adaptable to dock a container thereon; a shelf valve adaptable to connect to a container valve and a control interface adaptable to control the extension of the retractably extendible shelves.

In some embodiments, the system may further include a user interface for: (i) bypassing the control interface for locally controlling the movement of the retractable body and the provision of the atmosphere-controlling agent to the shelf valve, and for (ii) displaying data to a human operator relating to atmospheric conditions inside the container. The user interface may be configured to enable the provision of the atmosphere-controlling agent to the shelf valve, and to display data to a human operator relating to atmospheric conditions inside the container.

As part of the present disclosure, a method is provided of controlling atmospheric conditions in a container. In some embodiments, the method may include placing a container on a retractably extendible shelf and providing an atmosphere-controlling agent to the container.

In some embodiments, the container is placed on the retractably extendible shelf when in a first pre-defined position, which may be a fully-out position, though this is not necessarily so.

In some embodiments, the atmosphere-controlling agent may be provided to the container when the retractably extendible shelf is in a second pre-defined position, which may be a fully-in position, though this is not necessarily so. In some embodiments, the atmosphere-controlling agent may be provided to the container responsive to monitoring atmospheric conditions inside the container, such as humidity and oxygen. The atmosphere-controlling agent thus provided may maintain the humidity and oxygen inside the container within predetermined, or prescribed, levels.

In addition to the exemplary aspects and embodiments described above, further aspects and embodiments will become apparent by reference to the figures and by study of the following detailed description. In particular, it is noted that wafer storage containers are only an example for use of the retractably extendible shelf disclosed herein. The retractably extendible shelf may easily be adapted to serve different types and sizes of containers that are designed for storing or handling materials other than wafers.

### BRIEF DESCRIPTION OF THE FIGURES

Exemplary embodiments are illustarted in referenced figures. It is intended that the embodiments and figures disclosed herein are to be considered illustrative, rashter than restrictive. Aspects of the present invention may best be understood by reference to the following detailed description when read with the accompanying figures, in which:

FIG. 1 is a simplified three dimensional illustration of a supporting shelf according to some embodiments of the present disclosure;

FIG. 2 is a schematic three dimensional illustration of a wafers container mounted on a supporting shelf in a fully extended position, according to some embodiments of the present disclosure;

FIG. 3 is a schematic three dimensional illustration of a wafers container mounted on a supporting shelf in a stowed position, according to some embodiments of the present disclosure;

FIG. 4 is a schematic illustration of a supporting shelf valve according to some embodiments of the present disclosure;

FIG. 5 is a schematic partial side view of a supporting shelf and a wafer container according some embodiments of the present disclosure; and

FIGS. 6A-6C are schematic illustrations of a rack of supporting shelves according to some embodiments of the present disclosure.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE FIGURES

In the following detailed description, numerous specific details are set forth in order to provide a thorough understanding of the invention. However it will be understood by those of ordinary skill in the art that the present invention may be practiced without these specific details. In other instances, well-known methods, procedures, components and circuits have not been described in detail so as not to obscure the present invention.

It should be understood that the present invention may be used in a variety of applications. Although the present disclosure is not limited in this respect, the apparatus disclosed herein may be used in many systems such as in individual installation wall mounted intended to be included within the scope of the present disclosure include, by way of example only, free standing or in a stocking unit/system, which may be manual or robotically-operated, and the like.

A supporting shelf for wafer containers (hereinafter “supporting shelf”) is presented, which is capable of hosting large-scale wafers container. The supporting shelf is capable of, or designed for, controllably providing the large-scale wafer container with an atmosphere-controlling agent, which may be, for example, Nitrogen (N₂) The supporting shelf may provide the atmosphere-controlling agent to the wafer container both for inhibiting oxidation of the wafers stored inside the container, and for pressurizing the container to a pressure slightly above the exterior atmosphere, for preventing contaminating agents, such as air and dust particles, from entering the container.

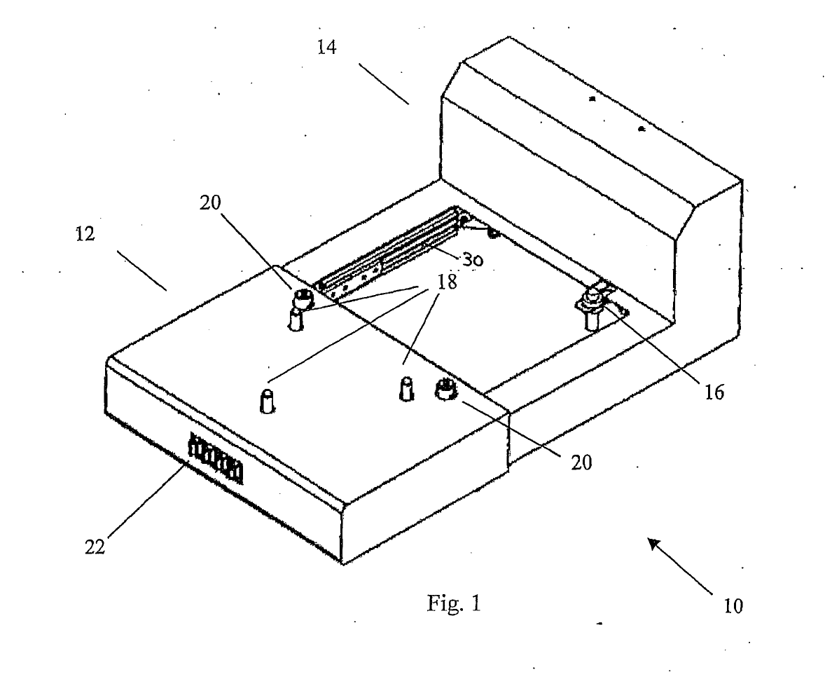

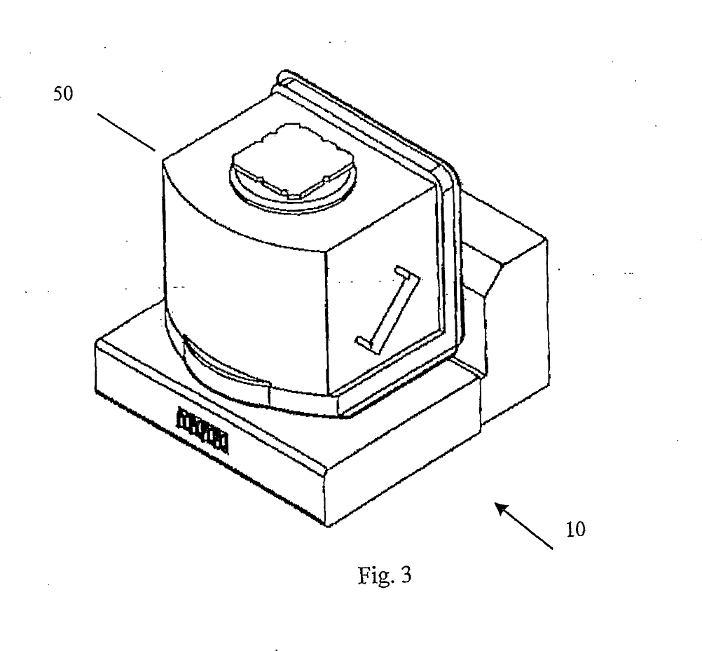

Reference is now made to FIG. 1, which is a simplified three-dimensional illustration of a supporting shelf (10) according to some embodiments. Supporting shelf 10 may include a first body 14 and a second body 12. The first and second bodies (14 and 12, respectively) may be adapted to be slidably moved relative to one another, such as by using sliding mechanism 30. According to some embodiments, first body 14 may be fixedly positioned. The second body 12 (herein ‘retractably extendible body’) may extend from a first pre-defined position to a second pre-defined position. For example, it may extend to a fully-out (fully extended) position (as demonstrated in FIG. 1, for example) and, if already in extended position, it may retract to a fully-in (stowed) position (as demonstrated in FIG. 3, for example). Retractably extendible body 12 may be extended to any position between the first pre-defined position and the second pre-defined position. Supporting shelf 10 may further include a location sensor such as proximity switch 16. Extendible body 12 may include one or more docking pins 18 (three docking pins are shown in FIG. 1), though one pin may suffice, one or more shelf valve 20, though one shelf valve may suffice, and user interface panel 22. Docking pins 18 may be adapted to fit into corresponding docking cavities, or grooves, in a wafer container (not shown). Of course, the second body 12 may have docking grooves instead of docking pins 18, in which case the container will have docking pins. In any case, the docking pins and docking grooves may be designed for convenient mutual engagement.

The one or more shelf valves 20 may each be designed and positioned so as to sealingly connect to a container valve of a wafer container when the container is docked onto extendible body 12, such as by being positioned onto docking pins 18. Shelf valve 20 may be connected to an atmosphere-control agent supply system (not shown).

Supporting shelf 10 may have at least two basic working positions. In the first position the extending body 12 may be in its stowed position. When in its ‘stowed’ position the atmosphere inside a wafer container may be controlled. In the second position, the extending body 12 may be substantially fully extended. When in its fully extended position, the container and, if so desired also the supporting shelf, may undergo service or maintenance operations. Stowed position may be detected by using a position sensitive device, such as proximity switch 16.

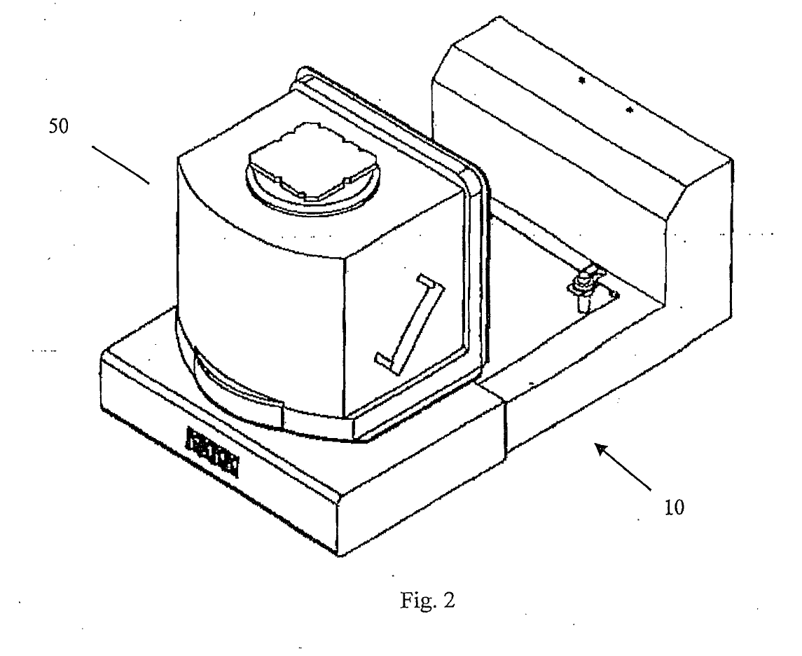

Reference is made now also to FIGS. 2 and 3, which are schematic three-dimensional illustration of a supporting shelf 10 with wafers container 50 according to some embodiments. FIG. 2 is a schematic illustration of supporting shelf 10 and wafer container 50 in an extended position. Wafer container 50 is sometimes called Front Opening Unified Pod (“FOUP”). FIG. 3 is a schematic illustration of supporting shelf 10 and wafer container 50 in stowed position. Wafer container 50 may be removed or placed on supporting shelf 10 when supporting shelf 10 is either in stowed position or in extended position. When supporting shelf is in its extended position, wafer container 50 may more easily be handled (removed from the shelf or placed on it) and this may facilitate the placement and removal of wafer container 50 by a robotic arm or machine. Placement of wafer container 50 on supporting shelf 10 so that docking pins 18 fit into their corresponding grooves in wafer container 50 may position the bottom of wafer container 50 substantially parallel to the upper face of extending body 12. Additionally, in this situation, the bottom of wafer container 50 may press the upper portion of valve 20 to cause it to form an open passage. Extending body 12 may be extended to facilitate the removal or placement of wafer container 50 therefrom/thereon. Once container 50 has been removed from, or placed on, extending body 12, extending body 12 may be retracted to its stowed position, for example.

When extendible part 12 is in a pre-defined position, for example in its stowed position, atmospheric conditions inside container 50, such as oxygen, temperature and relative humidity, may be controlled by providing atmosphere-controlling agent, such as Nitrogen, to the wafer container 50. In order to prevent untimely provision of atmosphere-controlling agent when extending body 12 is not in its stowed position, an electronic signal from proximity switch 16 may be used by a control system (not shown) to sense the actual position of the extendible body 12.

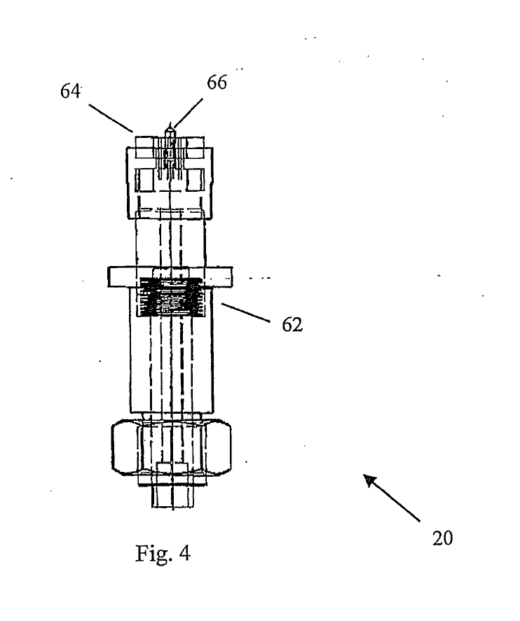

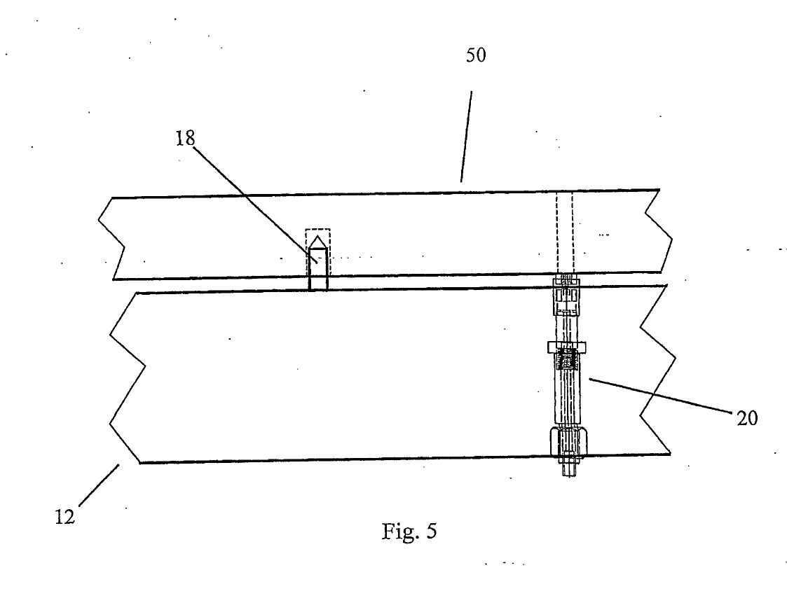

Reference is made now also to FIG. 4, which is a schematic illustration of a shelf valve 20 and to FIG. 5 which is a schematic partial side view of a supporting self 10 and a wafer container 50 according to some embodiments. Valve 20 may include a main body 62, a contact seal 64 and activation, needle-like, trigger 66. Supporting shelf 10 may include at least one valve such as valve 20, which may be installed on the first body (or on the second body, whichever the case may be) so that its upper end protrudes from the upper face of extending body 12 (FIG. 1). When wafer container 50 is placed onto supporting shelf 10 (FIG. 5) so that docking pins 18 properly enter their corresponding docking cavities in wafer container 50, ambient control material inlets in wafer container 50 are fitly placed on contact seals 64 and depress the respective activation triggers 66. The depression of activation trigger 66 may enable flow of ambient control material, such as Nitrogen, into or from wafer container 50, while contact seal 64 prevent that material from leaking outside of supporting shelf 10.

Supporting shelf 10 may be functionally connected to a control system (not shown) for controlling the atmosphere inside wafer container 50 (such as temperature, humidity, and so on.) by controlling the flow of atmosphere-control agent into I from wafer container 50. A user may control the operation of such control system via user interface panel 22 (FIG. 1) which may comprise indicators (such as operation indicators, humidity/temperature displays, gauges, etc.) and input means (such as keyboard, switches, depressible buttons, etc.). When supporting shelf 10 is not in its stowed position, proximity switch 16 may indicate the situation to the control system, for preventing flow of ambient controlling material through valve 20.

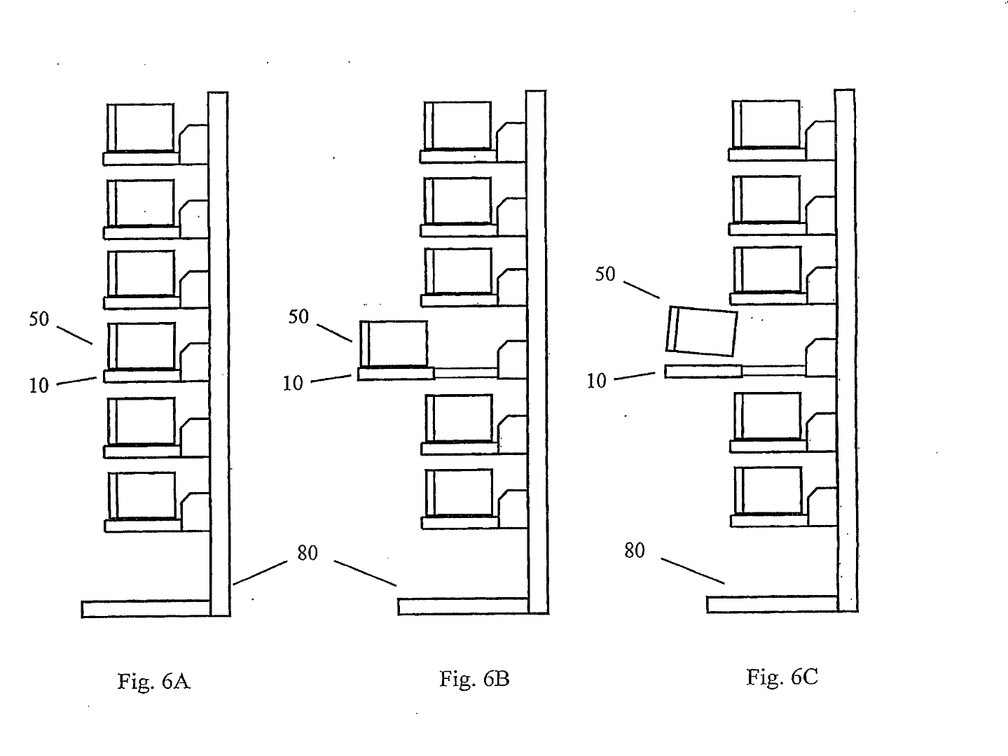

Reference is made now to FIGS. 6A, 6B and 6C, which are schematic illustrations of a rack 80 for supporting shelves 10 according to some embodiments. FIG. 6A illustrates a rack 80 where all its supporting shelves are in stowed position. FIG. 6B illustrates a rack 80 where one of its supporting shelves is in extended position. FIG. 6C illustrates a rack 80 where one of its supporting shelves is in extended position and its wafer container 50 is slightly departed from supporting shelf 10. Bringing extendible body 12 of supporting shelf 10 to its extended position may allow pulling container 50 from supporting shelf 10 or placing thereon a new container such as container 50. Once a container has been removed from extendible body 12, or a new container placed thereon, the extendible body 12 may be brought back to its stowed position and operation of a control system for that supporting shelf may be resumed.

While certain features of the present invention have been illustrated and described herein, many modifications, substitutions, changes, and equivalents will now occur to those of ordinary skill in the art. It is, therefore,-to be understood that the appended claims are intended to cover all such modifications and changes as fall within the true spirit of the invention.

What is claimed:

1. An apparatus comprising:
a retractably extendible shelf adaptable for supporting a container;
a docking member for docking said container; and
a shelf valve adaptable for engaging with a container valve.

2. The apparatus of claim 1, wherein the shelf valve and the container valve are adaptable form an open passage to the interior of said container.

3. The apparatus of claim 2, wherein the open passage is formed as a result of the pressure exerted by one valve on the other valve when the container is docked on the extendible shelf.

4. The apparatus of claim 3, wherein the extendible shelf comprises a first, fixed, body and a second, retractably extendible body that is adaptable to be slidably moveable relative to said fixed body between a fully-out position and a fully-in position.

5. The apparatus of claim 4, further comprising one or more location sensors for detecting when the extendible shelf is in a pre-defined position.

6. The apparatus of claim 5, wherein an atmosphere-controlling agent is provided to the shelf valve only if in a fully-in position.

7. The apparatus of claim 6, further comprising a control interface for remotely controlling the retractable body and the provision of the atmosphere-controlling agent to the shelf valve.

8. The apparatus of claim 7, further comprising a user interface for allowing a human operator to override the control interface, and for locally displaying data to the operator relating to atmospheric conditions inside the container.

9. A system for supporting a plurality of wafer containers, comprising:
a plurality of extendible shelves having a docking member adaptable to dock a container thereon;
a shelf valve adaptable to connect to a container valve; and
a control interface adaptable to control the extension of said extendible shelves.

10. The system of claim 9, wherein shelves further comprise a location sensor for detecting when the extendible shelves are in a pre-defined position.

11. The system of claim 9, wherein a shelf valve and a container valve are adapted to form an open passage to the interior of said container.

12. The system of claim 11, wherein the open passage is formed as a result of the pressure exerted by one valve on the other valve when the container is docked on the extendible shelf.

13. The system of claim 12, wherein each extendible shelf comprises a first, fixed, body and a second, retractable body that is adapted to be slidably moveable relative to the fixed body.

14. The system of claim 12, wherein an atmosphere-controlling agent may be provided to the container through the open passage only if in fully in position.

15. The system of claim 9, further comprising a user interface for: (i) bypassing the control system for locally controlling the movement of the retractable body and the provision of the atmosphere-controlling agent to the shelf valve, and for (ii) displaying data to a human operator relating to atmospheric conditions inside the container.

16. The system of claim 15, wherein the user interface enables the provision of the atmosphere-controlling agent to the shelf valve, and the displaying of data to a human operator relating to atmospheric conditions inside the container.

17. A method of controlling atmospheric conditions in a container, comprising:
placing a container on a retractably extendible shelf and providing an atmosphere-controlling agent to said container.

18. The method according to claim 17, wherein the container is placed on the retractably extendible shelf when in a first pre-defined position.

19. The method according to claim 17, wherein the providing occurs when the retractably extendible shelf is in a second pre-defined position.

20. The method according to claim 16, wherein the atmosphere-controlling agent is provided responsive to monitoring atmospheric conditions inside the container.
